(19) United States
(12) Patent Application Publication
(10) Pub. No.: US 2016/0181369 A1
(43) Pub. Date: Jun. 23, 2016

(54) JFET DEVICE AND ITS MANUFACTURING METHOD

(71) Applicants: Kaiming Ning, Shanghai (CN); Feng Jin, Shanghai (CN)

(72) Inventors: Kaiming Ning, Shanghai (CN); Feng Jin, Shanghai (CN)

(21) Appl. No.: 14/580,264

(22) Filed: Dec. 23, 2014

(51) Int. Cl. H01L 29/10; H01L 29/40; H01L 29/06; H01L 29/808; H01L 29/66

(52) U.S. Cl. CPC H01L 29/1058; H01L 29/808; H01L 29/66901; H01L 29/1095; H01L 29/0653; H01L 29/402

(57) ABSTRACT

The present invention discloses a JFET device, whose drift region is composed of a first deep well region doped with the second conduction type that is formed on a substrate doped with the first conduction type; the body region includes a second deep well region and channel region doped with the second conduction type; the channel region, located between the first deep well region and the second deep well region, includes two or more third deep well regions doped with the second conduction type that are arranged at equal intervals, with the doping impurities of the spacing region between the adjacent third deep well regions composed of the diffusion impurities of the adjacent third deep well regions; the processing conditions are the same for the three deep well regions. Regulating the pinch-off voltage of the JFET device by regulating the impurity concentration of the deep well region, and the width and number of the respective spacing regions. The present invention further discloses a method for manufacturing the JFET device. The present invention can reduce the pinch-off voltage, and regulate the pinch-off voltage conveniently, easy to meet the requirements for various pinch-off voltages.

### FIELD OF THE INVENTION

The present invention relates to the field of semiconductor integrated circuit manufacture, especially to a junction field effect transistor (JFET) device. The present invention further relates to a method for manufacturing the JFET device.

### BACKGROUND OF THE INVENTION

As shown in FIG. 1, which is a sectional view of an existing JFET device, a high-voltage (HV) N-channel JFET device is taken as an example as follows: An HV NJFET device is generally composed of two parts, one being the drift region 101 of the drain terminal, the other being the body region 102. The drift region 101 is mainly used for withstanding high voltage; since withstanding high voltage is required, an N well (NW), i.e. DNW104, is needed that is deep and dilute and formed in a P-substrate 103. However, since DNW104 cannot be so dilute as to affect the on-resistance, it needs to be relatively concentrated, with an additional inversion implantation layer (PTOP) 110 provided to balance its charge; that is, the balancing effect of PTOP110 enables the drift region not only to be further increased in concentration but also to keep higher voltage withstanding capability. The body region 102 is also composed of DNW104; in the body region 102 is formed a P well 105, which is formed by P-impurity implantation and used as a gate region, with DNW104 right under the P well 105 used as a channel region. A source region 106 and a drain region 107 composed of an N⁺ region are formed on the surface of the selected region of DNW104, respectively, and a gate lead-out region 108 composed of a P⁺ region is formed on the surface of the P well 105; the source region 106 is at a distance from the P well 105, and the field oxygen isolation region 109 is formed on the surface of DNW105 between the P well 105 and the drain region 107 and can be a Local Oxidation of Silicon layer (LOCOS). A drain-terminal polysilicon field plate 111 composed of polysilicon is formed on the surface of the field oxygen isolation region 109 adjacent to the drain terminal. The source region 106, the drain region 107 and the gate lead-out region 108 go through a contact hole 112 and a top metal layer 113, respectively, and lead out a source electrode S, a drain electrode D and a gate electrode G, respectively. Wherein the drain-terminal polysilicon field plate 111 is also led out to the drain electrode D through the contact hole 112 and the top metal layer 113. A lead-out region is also formed on the surface of the selected region of the substrate 103 and connected to the gate electrode G, and the channel region is pinched off by the P well 105 and the substrate 103 together, with the finally formed JFET device being a longitudinal pinch-off device.

The channel region of an existing HV NJFET device is composed of N-type impurities of a DNW104; when DNW104 (the S terminal of the source electrode) and PW105 (the G terminal of the gate electrode) are reversely biased, DNW 104 starts to be depleted until the channel region access is depleted and pinched off, which results a higher pinch-off voltage. In addition to the higher pinch-off voltage, the pinch-off voltage of the existing JFET device is completely determined by the concentration of the doping impurities of DNW104, PW105 and the substrate 103; as long as the process is fixed, the amount of the pinch-off voltage is relatively fixed, i.e., it is inconvenient to regulate the pinch-off voltage of the JFET device; when a variety of JFET devices having different pinch-off voltages need to be formed on one and the same wafer substrate, the impurity concentration of DNW104, PW105 and the substrate 103 of each of the devices needs to be regulated, which will increase the complexity of the process.

### CONTENTS OF THE INVENTION

A technical problem to be solved by the present invention is to provide a JFET device, which can reduce the pinch-off voltage and allow the pinch-off voltage to be regulated conveniently, easy to meet the requirements for various pinch-off voltages. For this, the present invention further provides a method for manufacturing the JFET device.

In order to resolve above technical problems, the JFET device provided by the present invention includes a drift region and a body region that are in lateral contact with each other.

The drift region is composed of a first deep well region doped with the second conduction type that is formed on a substrate doped with the first conduction type; a drain region is composed of a second-conduction-type heavily doped region formed in a selected region of the first deep well region; a drain electrode leads out at the top of the drain region.

The body region includes a second deep well region and channel region doped with the second conduction type, and in a selected region of the second deep well region is formed a source region composed of the second-conduction-type heavily doped region; a source electrode leads out from the top of the source region.

The channel region, located between the first deep well region and the second deep well region, is in lateral contact on both sides thereof with one of the first deep well region and the second deep well region, respectively; the source region and the drain region are at a distance from the channel region, respectively.

The channel region includes two or more third deep well regions doped with the second conduction type, between the adjacent two of which is a spacing region; each of the spacing regions, equal in width, is doped with the second conduction type, with the second-conduction-type doping impurities composed of the second-conduction-type impurities diffused from the adjacent third deep well region; the first deep well region, the second deep well region and the third deep well region have the same processing conditions, with two of the third deep well regions on the outmost side of the channel region being in lateral contact with one of the first deep well region and the second deep well region, respectively.

The pinch-off voltage of the JFET device is regulated by regulating the impurity concentration of the third deep well region, and the width and number of the respective spacing regions.

A gate region is composed of the substrate or a first-conduction-type well region formed at the top of the channel region, and in a selected region on the surface of the gate region is formed a gate lead-out region heavily doped with the first conduction type; a gate electrode leads out from the top of the gate lead-out region.

As a further improvement, a field oxygen isolation region is formed at the top of the first deep well region between the channel region and the drain region.

As a further improvement, an inversion implantation layer doped with the first conduction type is formed on the surface of the first deep well region at the bottom of the field oxygen isolation region.

As a further improvement, when the gate region includes the first-conduction-type well region, an inversion implantation layer is formed in the first-conduction-type well region; when the gate region is only composed of the substrate, in the channel region is formed the inversion implantation layer which has a suspension structure or is connected with the substrate.

As a further improvement, a drain-terminal polysilicon field plate is formed on the surface of the field oxygen isolation region adjacent to the drain region.

In order to resolve above technical problems, the method for manufacturing the JFET device of the present invention comprises the following steps:

Step 1: Providing a substrate doped with the first conduction type, and defining forming regions of the drift region and body region of the JFET device by a photoetching process; the forming region of the drift region is the forming region of the first deep well region doped with the second conduction type, and the forming region of the body region includes the forming region of the channel region and the second deep well region doped with the second conduction type.

A forming region of the two or more third deep well regions doped with the second conduction type that are arranged at equal intervals, between the adjacent two of which is a spacing region, is defined in the forming region of the channel region.

Step 2: Forming the first deep well region, the second deep well region and the third deep well region simultaneously by the ion implantation process; regulating the pinch-off voltage of the JFET device by regulating the impurity concentration of the third deep well region, and the width and number of the respective spacing regions; and performing the annealed drive-in.

The drift region is composed of the first deep well region after the annealed drive-in; the second-conduction-type impurities in the third deep well region diffuse into the spacing region by the annealed drive-in to get the spacing region doped with the second conduction type, with the annealed region composed of the third deep well region and the spacing region after the annealed drive-in; the body region is composed of the second deep well region and the channel region after the annealed drive-in, and the drift region is in lateral contact with the body region; the channel region, located between the first deep well region and the second deep well region, is in lateral contact on both sides thereof with one of the first deep well region and the second deep well region, respectively, with two of the third deep well regions on the outmost side of the channel region being in lateral contact with one of the first deep well region and the second deep well region, respectively.

Step 3: Forming the gate region, which is composed of the substrate or the first-conduction-type well region; when the gate region includes the first-conduction-type well region, the following step is needed: using the photoetching process to define the forming region of the first-conduction-type well region that is at the top of the channel region, with the first-conduction-type well region formed by ion implantation.

Step 4: Implanting second-conduction-type heavily doping ions simultaneously into a selected region on the surface of the first deep well region and the second deep well region, a drain region being composed of a second-conduction-type heavily doped region formed in the first deep well region, a source region being composed of a second-conduction-type heavily doped region formed in the second deep well region, the source region and the drain region being at a distance from the channel region, respectively.

Step 5: Forming a gate lead-out region by implanting the first-conduction-type heavily doping ions into a selected region on the surface of the gate region.

Step 6: Depositing a dielectric layer onto the surface of the substrate on which are formed the source region, the drain region and the gate lead-out region, forming a contact hole by etching, and filling the contact hole with metal to form a source electrode connected to the source region, a drain electrode connected to the drain region, and a gate electrode connected to the gate lead-out region, respectively.

As a further improvement, Step 3a is further included after the formation of the gate region in Step 3: a field oxygen isolation region is formed at the top of the first deep well region between the channel region and the drain region.

As a further improvement, Step 3b is further included after the formation of the field oxygen isolation region: an inversion implantation layer doped with the first conduction type is formed on the surface of the first deep well region at the bottom of the field oxygen isolation region by the photoetching process and ion implantation process.

As a further improvement, when the gate region includes the first-conduction-type well region, the inversion implantation layer is also simultaneously formed in the first-conduction-type well region in Step 3b; when the gate region is only composed of the substrate, in the channel region in Step 3b is also simultaneously formed the inversion implantation layer, which has a suspension structure or is connected with the substrate.

As a further improvement, Step 3c is further included after the formation of the field oxygen isolation region: first growing a gate oxide layer, then depositing a layer of polysilicon, and then photoetching the polysilicon so as to form a drain-terminal polysilicon field plate composed of the etched polysilicon on the surface of the field oxygen isolation region adjacent to the drain region.

The channel region of the device of the present invention has a segmental structure, i.e., it is formed by a plurality of deep well regions arranged at equal intervals that are interconnected after diffusion, with the impurities of the spacing region between the deep well regions formed by the impurity diffusion of the deep well regions. Compared with the prior art, the present invention can reduce the doping concentration of the channel region effectively, which makes the channel region easier to be depleted, thereby allowing a lower pinch-off voltage.

Besides, the present invention, simply by regulating the width of the spacing region between the deep well regions, can achieve a channel region having different effective doping concentration, thereby obtaining a device having a different pinch-off voltage. Therefore, the regulation for reducing the pinch-off voltage of the present invention neither needs to regulate the doping concentration of the deep well region, nor needs to change the processing conditions of the deep well region, thereby very easy to obtain a device having a different pinch-off voltage, easy to meet the users' needs for various pinch-off voltages.

### BRIEF DESCRIPTION OF THE DRAWINGS

The present invention will be further described below in detail with reference to drawings and embodiments:

FIG. 1 is a sectional view of an existing JFET device;

FIG. 2 is a sectional view of the JFET device in Example 1 of the present invention before drive-in;

FIG. 3 is a sectional view of the JFET device in Example 1 of the present invention after drive-in;

FIG. 4 is a curve diagram of relation between the pinch-off voltage and the width of the spacing region of the JFET device in Example 1 of the present invention;

FIG. 5 is a sectional view of the JFET device in Example 2 of the present invention before drive-in; and

FIG. 6 is a sectional view of the JFET device in Example 3 of the present invention before drive-in.

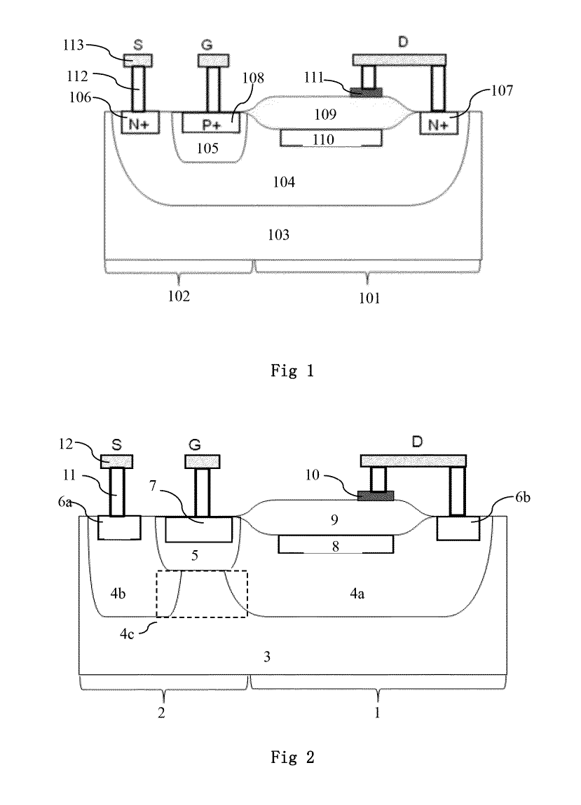

### DETAILED DESCRIPTION OF THE EMBODIMENTS

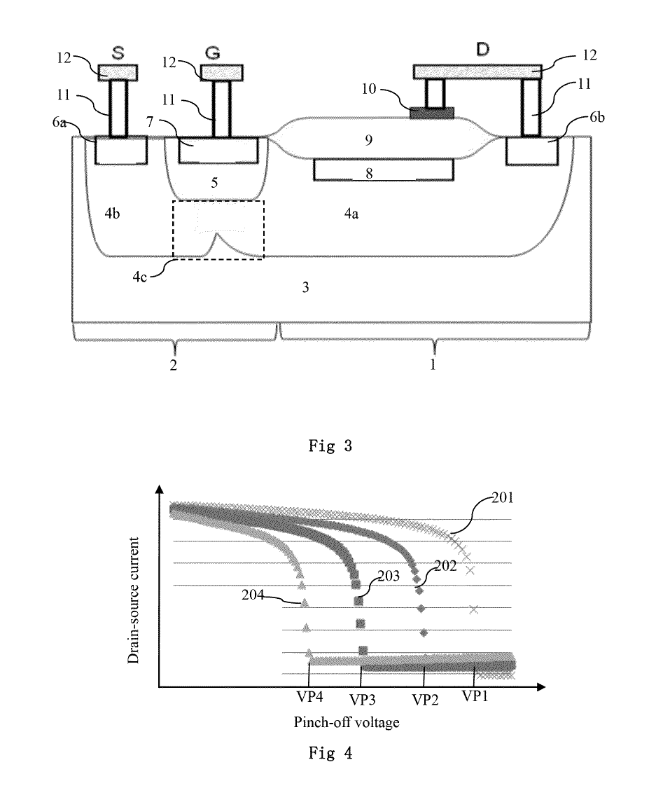

FIG. 2 is a sectional view of the JFET device in Example 1 of the present invention before drive-in; FIG. 3 is a sectional view of the JFET device in Example 1 of the present invention after drive-in; the JFET device in Example 1 of the present invention includes a drift region 1 and a body region 2 that are in lateral contact with each other.

The drift region 1 is composed of a first deep well region 4a doped with the second conduction type that is formed on a substrate 3 doped with the first conduction type; a drain region 6b is composed of a second-conduction-type heavily doped region formed in a selected region of the first deep well region 4a; a drain electrode D leads out through a contact hole 11 and a metal layer 12 at the top of the drain region 6b.

The body region 2 includes a second deep well region 4b and a channel region doped with the second conduction type, with the channel region located in a region indicated by a dashed box 4c. In a selected region of the second deep well region 4b is formed a source region 6a composed of the second-conduction-type heavily doped region; a source electrode S leads out through the contact hole 11 and the metal layer 12 at the top of the source region 6a.

The channel region, located between the first deep well region 4a and the second deep well region 4b, is in lateral contact on both sides thereof with one of the first deep well region 4a and the second deep well region 4b, respectively; the source region 6a and the drain region 6b are at a distance from the channel region, respectively.

The channel region includes two or more third deep well regions doped with the second conduction type, between the adjacent two of which is a spacing region; each of the spacing regions, equal in width, is doped with the second conduction type, with the second-conduction-type doping impurities composed of the second-conduction-type impurities diffused from the adjacent third deep well region; see the region indicated by the dashed box 4c in FIG. 2 for the spacing region before drive-in, and diffusion doping, and see the region indicated by the dashed box 4c in FIG. 3 for the spacing region after the diffusion doping. The first deep well region 4a, the second deep well region 4b and the third deep well region have the same processing conditions, and two of the third deep well regions on the outmost side of the channel region are in lateral contact with one of the first deep well region 4a and the second deep well region 4b, respectively. Example 1 of the present invention includes two third deep well regions, which are an extension portion of the first deep well region 4a and the second deep well region 4b, respectively, as indicated by the dashed box 4c.

Regulating the pinch-off voltage of the JFET device by regulating the impurity concentration of the third deep well region, and the width and number of the respective spacing regions.

A gate region is composed of a first-conduction-type well region 5 formed at the top of the channel region, and in a selected region on the surface of the gate region is formed a gate lead-out region 7 heavily doped with the first conduction type; a gate electrode G leads out through the contact hole 11 and the metal layer 12 at the top of the gate lead-out region 7. In other examples, it can also be achieved to form a substrate lead-out region heavily doped with the first conduction type on the surface of the substrate 3, and to make a substrate electrode lead out at the top of the lead-out region of the substrate, with the substrate electrode and the gate electrode G being interconnected, and thus the substrate 3 is also a part of the gate region and depletes the channel region from the bottom.

A field oxygen isolation region 9 is formed at the top of the first deep well region 4a between the channel region and the drain region 6b. An inversion implantation layer 8 doped with the first conduction type is formed on the surface of the first deep well region 4a at the bottom of the field oxygen isolation region 9; the inversion implantation layer 8 is used for balancing the charges in the drift region 1, enabling the drift region 1 to have increased doping concentration and thus reduced on-resistance while keep high voltage withstanding capability.

A drain-terminal polysilicon field plate 10 is formed on the surface of the field oxygen isolation region 9 adjacent to the drain region 6b. The drain-terminal polysilicon field plate 10 leads out the drain electrode D through the contact hole 11 and the metal layer 12.

The JFET in Example 1 of the present invention can be an N-type device, and can also be a P-type device; when the JFET is an N-type device, the first conduction type is P type, and the second conduction type is N type; when the JFET is a P-type device, the first conduction type is N type, and the second conduction type is P type.

The channel region in Example 1 of the present invention has low doping concentration, and can thus reduce the pinch-off voltage; the present invention can regulate the pinch-off voltage simply by regulating the width of the spacing region. FIG. 4 is a curve diagram of relation between the pinch-off voltage and the width of the spacing region of the JFET device in Example 1 of the present invention; in the diagram, the abscissa is the gate-source voltage, and the ordinate is the source-drain current. The curve 201 corresponds to the curve of the existing JFET device, and the curves 202, 203 and 204 correspond to the curves of the device of the example of the present invention, the widths of the spacing regions of the devices to which the curves 202, 203 and 204 correspond becoming greater successively, the deep well region of each of the devices having the same doping process conditions. It can be seen that the pinch-off voltages of the four curves are VP1, VP2, VP3 and VP4, respectively, and VP2, VP3 and VP4 are all less than VP1, and therefore the pinch-off voltage of the device in Example 1 of the present invention can be reduced. With VP2, VP3 and VP4 in a descending order, it is very easy for the present invention to regulate the pinch-off voltage by regulating the width of the spacing region.

As shown in FIGS. 2 and 3, the method for manufacturing the JFET device as provided in Example 1 of the present invention comprises the following steps:

Step 1: Providing a substrate 3 doped with the first conduction type, and defining forming regions of a drift region 1 and a body region 2 of a JFET device by the photoetching process; the forming region of the drift region 1 is the forming region of the first deep well region 4a doped with the second conduction type, and the forming region of the body region 2 includes the forming region of the channel region and the second deep well region 4b doped with the second conduction type.

A forming region of the two or more third deep well regions doped with the second conduction type that are arranged at equal intervals, between the adjacent two of which is a spacing region, is defined in the forming region of the channel region.

Step 2: An ion implantation process is used to form the first deep well region 4a, the second deep well region 4b and the third deep well region at the same time; regulating the pinch-off voltage of the JFET device by regulating the impurity concentration of the third deep well region, and the width and number of the respective spacing regions; and performing annealed drive-in.

The drift region 1 is composed of the first deep well region 4a after the annealed drive-in; the second-conduction-type impurities in the third deep well region diffuse into the spacing region by the annealed drive-in to get the spacing region doped with the second conduction type, with the annealed region composed of the third deep well region and the spacing region after the annealed drive-in; the body region 2 is composed of the second deep well region 4b and the channel region after the annealed drive-in, and the drift region 1 and the body region 2 are in lateral contact with each other; the channel region, located between the first deep well region 4a and the second deep well region 4b, is in lateral contact on both sides thereof with one of the first deep well region 4a and the second deep well region 4b, respectively; and two of the third deep well regions on the outmost side of the channel region are in lateral contact with one of the first deep well region 4a and the second deep well region 4b, respectively.

Step 3: Forming a gate region that is composed of the first-conduction-type well region 5; it comprises the following steps: using a photoetching process to define the forming region of the first-conduction-type well region 5 that is at the top of the channel region, with the first-conduction-type well region 5 formed by the ion implantation.

It also comprises the following steps:

Step 3a: A field oxygen isolation region 9 is formed at the top of the first deep well region 4a between the channel region and the drain region 6b. Preferably, the field oxygen isolation region 9 is formed by the LOCOS process.

Step 3b: An inversion implantation layer 8 doped with the first conduction type is formed on the surface of the first deep well region 4a at the bottom of the field oxygen isolation region 9 by the photoetching process and ion implantation process.

Step 3c: First growing a gate oxide layer, then depositing a layer of polysilicon, and then photoetching the polysilicon so as to form a drain-terminal polysilicon field plate 10 composed of the etched polysilicon on the surface of the field oxygen isolation region 9 adjacent to the drain region 6b.

Step 4: Implanting the second-conduction-type heavily doping ions simultaneously into a selected region on the surface of the first deep well region 4a and the second deep well region 4b, a drain region 6b being composed of a second-conduction-type heavily doped region formed in the first deep well region 4a, a source region 6a being composed of a second-conduction-type heavily doped region formed in the second deep well region 4b, the source region 6a and the drain region 6b being at a distance from the channel region, respectively.

Step 5: A gate lead-out region 7 is formed by implanting the first-conduction-type heavily doping ions into a selected region on the surface of the first-conduction-type well region 5. When the substrate 3 is also a part of the gate region, forming a substrate lead-out region by implanting the first-conduction-type heavily doping ions into the surface of a selected region of the substrate 3, with the substrate lead-out region being the gate lead-out region 7 on the surface of the substrate 3.

Step 6: Depositing a dielectric layer onto the surface of the substrate 3 on which are formed a source region 6a, a drain region 6b and a gate lead-out region 7, forming a contact hole 11 by etching, and filling the contact hole 11 with metal and forming a metal layer 12, so as to form a source electrode S connected to the source region 6a, a drain electrode D connected to the drain region 6b, and a gate electrode G connected to the gate lead-out region 7, respectively. The drain-terminal polysilicon field plate 10 is connected to the drain electrode D through the contact hole 11 and the metal layer 12.

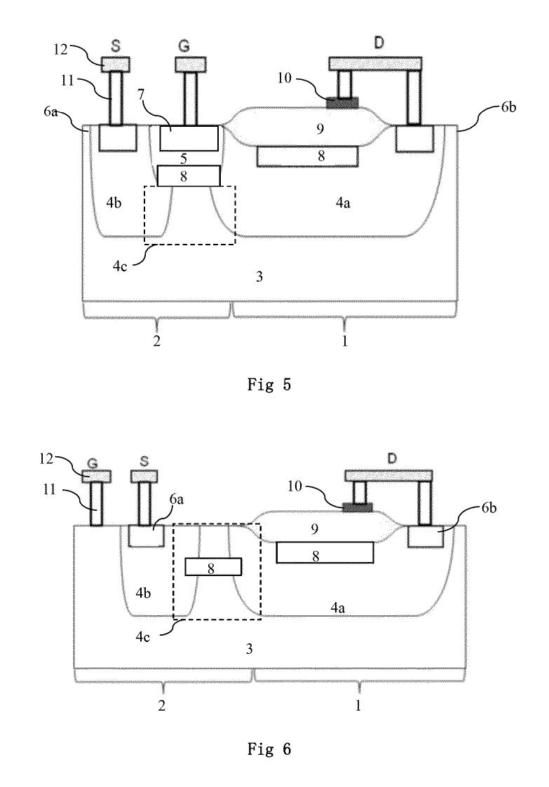

FIG. 5 is a sectional view of the JFET device in Example 2 of the present invention before drive-in. Examples 1 and 2 of the present invention are distinguished from each other in the following aspect: The inversion implantation layer 8 is formed in the first-conduction-type well region 5 in Example 2 of the present invention.

The manufacturing method in Example 2 of the present invention is distinguished from that in Example 1 of the present invention in the following aspect: The inversion implantation layer 8 is simultaneously formed in the first-conduction-type well region 5 in Step 3b of Example 2 of the present invention.

FIG. 6 is a sectional view of the JFET device in Example 3 of the present invention before drive-in; Examples 1 and 3 of the present invention is distinguished from each other in the following aspects: In Example 3 of the present invention, the gate region is only composed of the substrate 3, i.e., the gate region does not include the first-conduction-type well region 5; in the channel region is simultaneously formed the inversion implantation layer 8, which has a suspension structure or is connected with the substrate 3.

The manufacturing method in Example 3 of the present invention is distinguished from that in Example 1 of the present invention in the following aspect: Example 3 of the present invention does not include the step for forming the first-conduction-type well region 5. In the channel region in Step 3b is also simultaneously formed the inversion implantation layer 8, which has a suspension structure or is connected with the substrate 3.

The present invention is described above in detail through specific examples, which however do not restrict the present invention. Without departing from the principle of the present invention, those skilled in the art may also make many alterations and improvements, which should also be considered to be within the scope of protection of the present invention.

1. A JFET device, comprising:
a drift region and a body region that are in lateral contact with each other;
the drift region is composed of a first deep well region doped with a second conduction type that is formed on a substrate doped with a first conduction type; a drain region is composed of a second-conduction-type heavily doped region formed in a selected region of the first deep well region; a drain electrode leads out at the top of the drain region;
the body region includes a second deep well region and channel region doped with the second conduction type, and in a selected region of the second deep well region is formed a source region composed of the second-conduction-type heavily doped region; a source electrode leads out from the top of the source region;
the channel region, located between the first deep well region and the second deep well region, is in lateral contact on both sides thereof with one of the first deep well region and the second deep well region, respectively; the source region and the drain region are at a distance from the channel region, respectively;
the channel region includes two or more third deep well regions doped with the second conduction type, between the adjacent two of which is a spacing region; each of the spacing regions, equal in width, is doped with the second conduction type, with the second-conduction-type doping impurities composed of the second-conduction-type impurities diffused from the adjacent third deep well region; the first deep well region, the second deep well region and the third deep well region have the same processing conditions, with two of the third deep well regions on the outmost side of the channel region being in lateral contact with one of the first deep well region and the second deep well region, respectively;
regulating pinch-off voltage of the JFET device by regulating impurity concentration of the third deep well region, and width and number of the spacing regions;
a gate region is composed of the substrate or a first-conduction-type well region formed at the top of the channel region, and in a selected region on the surface of the gate region is formed a gate lead-out region heavily doped with the first conduction type; a gate electrode leads out from the top of the gate lead-out region.

2. The JFET device according to claim 1, wherein a field oxygen isolation region is formed at the top of the first deep well region between the channel region and the drain region.

3. The JFET device according to claim 2, wherein an inversion implantation layer doped with the first conduction type is formed on the surface of the first deep well region at the bottom of the field oxygen isolation region.

4. The JFET device according to claim 3, wherein when the gate region includes the first-conduction-type well region, the inversion implantation layer is formed in the first-conduction-type well region; when the gate region is only composed of the substrate, in the channel region is formed the inversion implantation layer that has a suspension structure, or the inversion implantation layer in the channel region is connected with the substrate.

5. The JFET device according to claim 2 wherein a drain-terminal polysilicon field plate is formed on the surface of the field oxygen isolation region adjacent to the drain region.

6. A method for manufacturing the JFET device, comprising the following steps:
Step 1: providing a substrate doped with a first conduction type, and defining a forming region of the drift region and body region of the JFET device by a photoetching process; the forming region of the drift region is a forming region of a first deep well region doped with a second conduction type, and a forming region of the body region includes a forming region of the channel region and a second deep well region doped with the second conduction type;
a forming region of the two or more third deep well regions doped with the second conduction type that are arranged at equal intervals, between the adjacent two of which is a spacing region, is defined in the forming region of the channel region;
Step 2: forming the first deep well region, the second deep well region and the third deep well region simultaneously by an ion implantation process; regulating the pinch-off voltage of the JFET device by regulating the impurity concentration of the third deep well region, and the width and number of the respective spacing regions; and performing annealed drive-in;
the drift region is composed of the first deep well region after the annealed drive-in; the second-conduction-type impurities in the third deep well region diffuse into the spacing region by the annealed drive-in to get the spacing region doped with the second conduction type, with the annealed region composed of the third deep well region and the spacing region after the annealed drive-in; the body region is composed of the second deep well region and the channel region after the annealed drive-in, and the drift region is in lateral contact with the body region; the channel region, located between the first deep well region and the second deep well region, is in lateral contact on both sides thereof with one of the first deep well region and the second deep well region, respectively, with two of the third deep well regions on the outmost side of the channel region being in lateral contact with one of the first deep well region and the second deep well region, respectively;
Step 3: forming the gate region, which is composed of the substrate or the first-conduction-type well region; when the gate region includes the first-conduction-type well region, the following step is needed: using a photoetching process to define a forming region of the first-conduction-type well region that is at the top of the channel region, with the first-conduction-type well region formed by the ion implantation;
Step 4: implanting second-conduction-type heavily doping ions simultaneously into a selected region on the surface of the first deep well region and the second deep well region, a drain region being composed of a second-conduction-type heavily doped region formed in the first deep well region, a source region being composed of a second-conduction-type heavily doped region formed in the second deep well region, the source region and the drain region being at a distance from the channel region, respectively;
Step 5: forming a gate lead-out region by implanting the first-conduction-type heavily doping ions into a selected region on the surface of the gate region;
Step 6: depositing a dielectric layer onto the surface of the substrate on which are formed the source region, the drain region and the gate lead-out region, forming a contact hole by etching, and filling the contact hole with metal to form a source electrode connected to the source region, a drain electrode connected to the drain region, and a gate electrode connected to the gate lead-out region, respectively.

7. The method according to claim 6, wherein Step 3a is further included after the formation of the gate region in Step 3: a field oxygen isolation region is formed at the top of the first deep well region between the channel region and the drain region.

8. The method according to claim 7, wherein Step 3b is further included after the formation of the field oxygen isolation region: an inversion implantation layer doped with the first conduction type is formed on the surface of the first deep well region at the bottom of the field oxygen isolation region by the photoetching process and ion implantation process.

9. The method according to claim 8, wherein when the gate region includes the first-conduction-type well region, the inversion implantation layer is also simultaneously formed in the first-conduction-type well region in Step 3b; when the gate region is only composed of the substrate, in the channel region in Step 3b is also simultaneously formed the inversion implantation layer, which has a suspension structure or is connected with the substrate.

10. The method according to claim 7, wherein Step 3c is further included after the formation of the field oxygen isolation region: first growing a gate oxide layer, then depositing a layer of polysilicon, and then photoetching the polysilicon so as to form a drain-terminal polysilicon field plate composed of the etched polysilicon on the surface of the field oxygen isolation region adjacent to the drain region.

11. The JFET device according to claim 3, wherein a drain-terminal polysilicon field plate is formed on the surface of the field oxygen isolation region adjacent to the drain region.

12. The method according to claim 8, wherein Step 3c is further included after the formation of the field oxygen isolation region: first growing a gate oxide layer, then depositing a layer of polysilicon, and then photoetching the polysilicon so as to form a drain-terminal polysilicon field plate composed of the etched polysilicon on the surface of the field oxygen isolation region adjacent to the drain region.
